(19) United States
(12) Patent Application Publication
(10) Pub. No.: US 2012/0163621 A1
(43) Pub. Date: Jun. 28, 2012

(54) ORIGINAL EQUIPMENT MANUFACTURER ("OEM") INTEGRATION AMPLIFIER

(76) Inventors: Brett D. Riggs, Yorba Linda, CA (US); Sam W. Grove, Irvine, CA (US); Nathaniel Lee Wincek, New Port Richey, FL (US)

(21) Appl. No.: 13/336,350

(22) Filed: Dec. 23, 2011

Related U.S. Application Data
(60) Provisional application No. 61/426,632, filed on Dec. 23, 2010.

(51) Int. Cl. H04B 1/00; H03G 3/00

(52) U.S. Cl. 381/86; 381/107

(57) ABSTRACT

Embodiments of the proposed invention preferably provide systems and methods for an improved aftermarket automobile audio amplifier that is easy to install while integrating and improving OEM functionality. Embodiments of the invention preferably directly connect to preexisting OEM wiring and hardware. Embodiments of the invention preferably preserve OEM system functionality and allow for integration of additional auxiliary inputs. A digital signal processing module preferably adjusts an output volume to ensure that auxiliary inputs are audible to a vehicle occupant at an appropriate and comfortable volume level. Therefore, vehicle OEM safety chimes or third party navigational commands may be output to a vehicle occupant at an appropriate volume level irrespective of the presence, absence or volume level of other audio signal outputs. Furthermore, the direct connection to preexisting OEM wiring and hardware preferably allows for both easy installation and easy removal of embodiments of the current invention.

### CROSS-REFERENCE TO RELATED APPLICATION

This application is a nonprovisional of U.S. Provisional Application No. 61/426,632 filed on Dec. 23, 2010 which is hereby incorporated by reference in its entirety.

### FIELD OF TECHNOLOGY

Aspects of the invention relate to an aftermarket audio amplifier that may be integrated into a preexisting OEM system.

### BACKGROUND

Today many vehicles are built by an OEM with pre-installed audio and entertainment systems. However, for some customers the pre-installed audio systems do not offer the quality or features desired. For example, some enthusiasts may desire higher performing audio systems and some would like to add customized features not included in the OEM system. To obtain the features and performance they desire, customers may turn to aftermarket manufactures of audio equipment.

The aftermarket manufactures supply audio products such as amplifiers, speakers and subwoofers that may be added to a vehicle's OEM system or may replace the vehicle's OEM system. Exemplary features that may be integrated into an aftermarket system may include navigation, telephone calling, voice recognition commands and MP3 player functionality.

A challenge facing aftermarket manufactures is to ensure that later added equipment does not interfere with pre-installed OEM features of a vehicle. For example, some OEM safety alerts are routed through the OEM radio and/or stereo. When installing aftermarket equipment, care must be taken to preserve the operational integrity of OEM safety features and associated alerts.

An OEM safety alert may include a chime indicating a vehicle malfunction or detection of a vehicle occupant not wearing a safety belt. For example, upon detection that a vehicle occupant has not fastened a safety belt, a signal may be passed along the OEM system data bus instructing the OEM system that a safety chime should be generated to remind the occupant to fasten the safety belt.

Under certain operating conditions, an OEM audio system may not preserve the full operational integrity of a vehicle's safety features. Such conditions may arise due to the fact that an audible volume of an OEM safety chime is preset by the OEM. The preset volume allows the chime to be routed through the OEM audio system and prevents the volume control of the audio system from controlling the volume of the safety chime. If the safety chime volume was not preset, there may be instances when the volume of the safety chime would be excessively loud or overly quiet.

For example, if the volume of the audio system was left at a high level when the vehicle was turned off, when the vehicle is turned back on at a later time, a safety chime reminding an occupant to fasten a safety belt may be produced at the previously set high volume. Such a sudden, loud and unanticipated chime may be frightening and unhealthy to a vehicle occupant. To avoid this problem, and to allow safety chimes to be produced by a standard audio system, OEM safety chimes are preset to a specific volume level, irrespective of a currently set volume of the audio system.

While the preset safety chime volume level of OEM systems prevents loud and/or soft and/or unanticipated chimes, it may not allow the chimes to be heard under all operating conditions. If a vehicle occupant desires to listen to audio at a high volume, the preset volume level of safety chimes may not be loud enough to be heard over the high volume level set by the occupant. Therefore, even when using an OEM system, when a vehicle occupant is listening to audio at a high volume, the occupant may not be alerted to vehicle safety concerns.

The preset OEM volume of safety chimes poses an additional challenge to aftermarket manufacturers. If a component of an OEM system is replaced, safety chimes may now be routed through an aftermarket amplifier system and the preset volume level of the safety chime may be amplified to a level commensurate with all audio signals. If the gain of the aftermarket amplifier system has been set at a high level, the preset volume level of a safety chime will be amplified accordingly. Therefore, a vehicle occupant may be presented with a sudden, loud and/or unanticipated safety chime which may be frightening and unhealthy to the occupant.

To preserve the integrity of vehicle OEM safety chimes, aftermarket manufactures have developed a work-around. Typically the OEM safety chimes are only generated on one channel at the front of a vehicle. (The chimes may be generated on any channel.) Instead of connecting an aftermarket amplifier to a front channel of an OEM system, only rear channels are connected, or any channel that does not carry the safety chime. A line is run from the channels that do not carry the safety chimes to channels that do carry the safety chimes. Therefore, if safety chimes are generated on a front channel, a line would be run from the rear channels to the front channel giving a faux impression of independent operation of the front channels.

The aforementioned workaround may also avoid the problem of excessive amplification of the OEM safety chimes. Because signals of a channel only pass through the aftermarket amplifier if safety chimes are not generated on the channel, an OEM safety chime generated may be output at the OEM preset volume level. However, the work-around has presented other challenges such as implementing “fading” functionality, where the volume is adjusted between front and rear channels. The workaround also does not ensure that the chime remains audible under diverse operating conditions.

Aftermarket manufacturers have developed a patchwork of solutions as further problems have arisen. However, a comprehensive integrated solution has not yet been achieved.

A further challenge facing both OEM and aftermarket manufacturers is integrating additional functional features into an audio system. For example, one may wish to integrate navigation, telephone calling, an MP3 player and/or voice recognition commands into an audio system. Integration of additional features may involve the coordination of different audio system components.

For example, if one is listening to music on the radio, a navigational instruction should be heard irrespective of the volume level set by a listener. Conversely, if the radio is off, a navigational command should be delivered at a volume that is not excessively loud or overly quiet.

As a further example, an OEM audio system may allow an occupant to make an adjustment to an audio setting. Exemplary audio setting may include treble, bass or equalizer settings. The adjustments of the occupant should be seamlessly reflected in an output generated by an aftermarket amplifier.

Another challenge facing aftermarket manufactures is the perceived complexity of installing aftermarket audio equipment. While many may enjoy higher quality audio in their vehicle, the thought of having to remove and replace OEM components may be too daunting. Perceived and actual complexity may discourage some vehicle owners from upgrading their OEM audio system.

Accordingly, there is a need for an improved aftermarket audio amplifier that is easy to install, integrates desired features of an OEM system and provides increased customization and performance over an OEM system.

### SUMMARY OF THE INVENTION

It is an object of this disclosure to provide apparatus and methods for an aftermarket audio amplifier. Embodiments may be configured to detect a first audio setting, detect an audio input, adjust a gain or other setting to correspond to a second audio setting and generate an output based on the audio input and the second audio setting.

Embodiments may be configured to detect data activity occurring on a system data bus in a vehicle, identify the data activity and generate an output based on the data activity.

Methods may include detecting a user-defined audio setting, detecting an audio input, the audio input associated with an amplifier-defined audio setting and in response to detecting the audio input, applying the amplifier-defined audio setting to the audio input.

### BRIEF DESCRIPTION OF THE DRAWINGS

The objects and advantages of the invention will be apparent upon consideration of the following detailed description, taken in conjunction with the accompanying drawings, in which like reference characters refer to like parts throughout, and in which:

FIG. 1 shows various system components that may be used in conjunction with the current invention;

FIG. 2 shows a schematic of an embodiment of a circuit according to the current invention;

FIGS. 2.1-2.9 show more detailed circuit schematics of the schematic diagram shown in FIG. 2;

FIG. 3 shows a flow chart of an illustrative process in accordance with principles of the invention; and

FIG. 4 shows a schematic diagram of a general purpose computing environment in which one or more aspects of the present invention may be implemented.

### DETAILED DESCRIPTION OF THE INVENTION

Apparatus and methods for providing an aftermarket automobile audio amplifier are provided. The amplifier is preferably easy to install and integrates and improves OEM functionality of the automobile. Embodiments include an audio amplifier that may quickly be exchanged with an OEM amplifier to provide higher power, increased audio quality and increased functionality over the OEM amplifier. Embodiments preferably alert a vehicle occupant to vehicle safety chimes and/or particular audio signals irrespective of a selected volume or other setting of the vehicle's audio system.

Embodiments preferably directly connect to preexisting OEM amplifier wiring so that an amplifier may be easily installed. Embodiments may connect directly to a system data bus present in the vehicle.

Such seamless integration of an aftermarket amplifier with preexisting OEM wiring and functionality allows for a predictable and simple installation that is easily reversible when possession of a vehicle is transferred. The amplifier may preferably be easily removed when the car is sold or at the end of a lease.

Preferably, no additional third party adapters are required to ensure compatibility with OEM wiring and/or other preexisting OEM equipment. Because of the connection to preexisting OEM wiring and/or data communication systems, it may be unnecessary to search for obscure wires or to connect to additional interfaces. Accordingly the amplifier may be easily installed in a vehicle.

Embodiments may be powered-on by detection of an authorized vehicle ignition implement. Embodiments may be powered-on by detection of data activity on the system data bus.

The connection to preexisting OEM wiring preferably provides high quality audio amplification without disrupting OEM functionality. Embodiments preferably retain OEM functions. Exemplary OEM functions may include steering wheel controls, Bluetooth, OnStar™ and safety chimes.

Additionally, embodiments may maintain the preexisting OEM “head unit” functionality. A head unit is a component of vehicle audio system that provides an occupant interface for adjusting components of a vehicle's audio system. For example, the head unit may include controls for adjusting audio settings such as volume, tuning the radio, and bass or treble levels.

Furthermore, OEM features may be improved without complex rewiring. Some embodiments may include built in signal processing preconfigured with multiple settings for optimum sound quality in the vehicle. The multiple settings may allow the audio sound to be changed depending on the type of vehicle or genre of music selected by a vehicle occupant.

Improvements over OEM functionality may include integrating and auto-adjusting an audible volume of an input. Irrespective of increased amplification and/or occupant adjusted volume settings, an input may be seamlessly presented to a vehicle occupant at an appropriate and comfortable audible volume.

Apparatus may include an amplifier configured to detect a first volume setting, detect an audio input, adjust a gain of the amplifier to correspond to a second volume setting and generate an output based on the audio input and the second volume setting.

The volume setting may correspond to a level gain of the amplifier. A level of gain of the amplifier may correspond to a magnitude of loudness audible to a vehicle occupant transmitted via the vehicle's speakers.

For example, a vehicle occupant may choose to listen to music stored on a portable MP3 device at a first volume setting. If an amplifier output is based on the music, vehicle safety chime and first volume setting, the occupant may be unable to discern the safety chime. The first volume setting may be too loud or otherwise inappropriate for an output based, in part, on the vehicle safety chime.

A second volume setting may be associated with the vehicle safety chime. Upon detection of the vehicle safety chime, the amplifier may generate an output based on the safety chime and the associated second volume setting. The output may correspond to a safety chime that is audible to the occupant at an appropriate volume level.

The first volume setting may correspond to a greater magnitude of gain of the amplifier than that of the second volume setting.

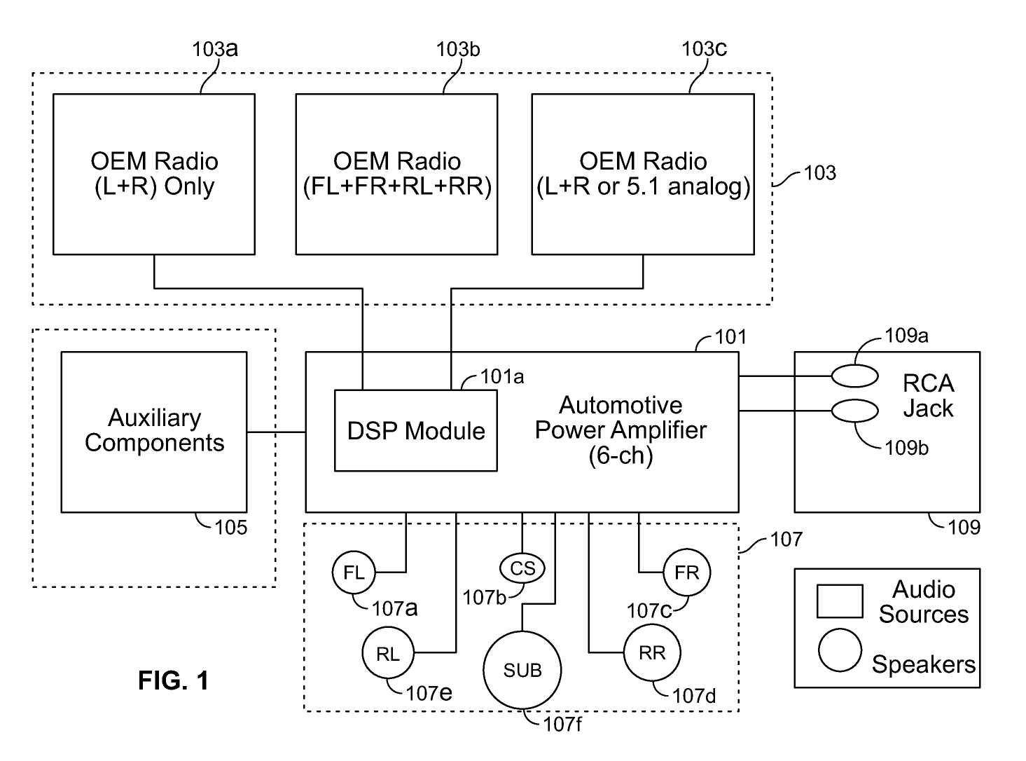

The second volume setting may be associated with an audio input. Exemplary inputs include a navigation instruction, a phone conversation or an auxiliary input (see FIG. 1, item 105). The second volume setting may correspond to a volume level appropriate for the associated audio input. Each input may be associated with a respective second volume setting. The respective second volume setting may be selected by a vehicle occupant, amplifier user or defined by the amplifier.

The first volume setting may be associated with a first input and the second volume setting may be associated with a second input. Embodiments may apply the first volume setting to the first input and the second volume setting to the second input. Following the applying, an amplifier output may be generated based on the first input and the second input.

Upon detection of the second input, some embodiments may suspend generation of an output based on the first input. The suspension may effectively mute the first input for a duration of time. The duration may correspond to a period of time required to generate an amplifier output based on the second input and the second volume setting or any other suitable time period. The second input may correspond to a vehicle safety chime, a navigation instruction or a phone conversation.

Applying the first volume setting to the first input may adjust a level of gain of the amplifier applied to the first input. Applying the second volume setting to the second input may adjust a level of gain of the amplifier applied to the second input.

For example, a vehicle occupant may be listening to music when the amplifier detects an incoming phone call or an OEM safety chime. Embodiments may lower the gain of the music to the extent needed to ensure that the safety chime or phone call may be heard by the occupant at an appropriate volume level.

The second volume setting may correspond to a greater magnitude of gain of the amplifier than that of the first volume setting. For example, embodiments may raise an output volume level of a vehicle safety chime to enable the chime to be heard over the volume level associated with another concurrent input. Embodiments may lower the level of gain applied to the music and raise the level of gain applied to the chime.

Following generation of an output based on the audio input and the second volume setting, embodiments may be configured to re-adjust the gain of the amplifier. The re-adjusted gain may correspond to the first volume setting.

For example, a vehicle occupant may be listening to music at a first volume setting. Upon detection of an OEM safety chime, the amplifier may generate an output based on the chime and the second volume setting. Following generation of an output based on the safety chime, the amplifier may resume generating the output based on the music and the first volume setting.

As a further example, the amplifier may detect an incoming phone call. In response to the detection, the amplifier may lower an audible volume of the music for a duration of the phone call. Upon completion of the phone call, the amplifier may raise the audible volume of the music.

Embodiments may be configured to detect an input based on data activity on the system data bus. A connection with the OEM wiring preferably provides access to an OEM system data bus. The connection with OEM wiring may be a direct connection. The OEM system data bus may carry one or more signals instructing an OEM audio system to generate a safety chime. The signals on the OEM data bus may contain information relating to the duration of a safety chime.

For example, a safety chime or incoming phone call may be detected by identification of data activity on the system data bus. A safety chime may be associated with a signature digital signal or a specific input receiver. An incoming phone call may be associated with a signature digital signal or a specific input receiver. The specific input receiver may be an auxiliary input receiver. The safety chime or phone call may be identified based on the associated signature digital signal or specific input receiver.

In some vehicles, there may be a time delay from a time that a signal appears on the OEM system data bus until the chime is actually generated. The OEM data bus is preferably monitored for signals indicating a safety chime has been generated or is imminently audible. Some vehicles may include a delay between when the chime signal appears on the OEM data bus and when the chime is input to an amplifier. The delay may be a sufficient amount of time for embodiments of the current invention to preferably react and make adjustments to a volume setting.

Upon detection of a chime signal on the OEM system data bus, an embodiment may be configured to generate its own safety chime. In these embodiments, it may not be necessary to adjust a volume setting within the period of delay between when the signal appears on the OEM system data bus and an audible chime. In some embodiments, the ability of the OEM system to produce an audible safety chime may be disabled.

Apparatus may include an aftermarket audio amplifier, the amplifier configured to detect an input, identify the input and apply an equalizer configuration associated with the input.

Exemplary inputs may include an instruction of a navigation system, a portion of a conversation conducted using a mobile device and a vehicle safety chime. The input may be any suitable audio input.

For example, a vehicle occupant may select an equalizer configuration that is optimized for a particular genre of music. The equalizer configuration selected by the occupant, when applied to an input corresponding to a phone conversation, may distort the phone conversation. If the amplifier identifies an input as a phone conversation, the amplifier may apply an equalizer configuration associated with the input that will not distort the input.

Embodiments may include equalizer configurations that allow for adjustment across a range of frequencies For example, an equalizer configuration may allow adjustment of frequencies between 20 Hz to 20 kHz.

In some embodiments, a quality factor (“Q”) associated with a band of frequencies may be adjusted. The Q is a ratio of a center frequency in a band of frequencies the width of the band of frequencies. Embodiments may provide parametric equalization. For a band of frequencies, embodiments may provide adjustability over a center frequency of the band, gain of the band and control of the Q.

The equalizer configuration may be optimized for a frequency range associated with human conversational speech. For example, the equalizer configuration may attenuate frequencies below 300 Hz and above 3,400 Hz.

Equalizer configurations may include adjustable “peak” and/or “shelf” filters. A “peak” or “shelf” filter may be configured to attenuate and/or accentuate frequencies above or below a specified cut-off frequency.

Embodiments may be configured to apply a gain configuration associated with the input. An input may be associated with an equalizer configuration and a gain configuration. Embodiments may be configured to detect the input and apply the associated equalizer configuration and the associated gain configuration.

A vehicle occupant may select a gain configuration that corresponds to a high level of loudness. The occupant selected gain configuration may be unsuitable for an input that corresponds to a vehicle safety chime or other input.

For example, upon detection and identification of an input corresponding to a vehicle safety chime, the amplifier may apply a gain configuration associated with the safety chime. The gain configuration associated with the chime may correspond to a loudness level lower than the gain configuration selected by the occupant. Applying the gain configuration associated with the chime may ensure that the chime is output at an appropriate loudness level.

Embodiments may be configured to monitor a system data bus in a vehicle. Embodiments may be configured to identify data activity on the system data bus. The identified data activity may include an audio configuration. An amplifier output may be generated based on the audio configuration.

For example, the data activity may be identified as an audio configuration including an equalizer configuration. An output may be generated based on the equalizer configuration. As a further example, data activity may be identified as an audio configuration including volume, bass treble, balance and fade selections. An amplifier output may include the volume, bass treble, balance and fade selections.

Methods of integrating an aftermarket audio amplifier into a vehicle are provided. The method may include detecting a user-defined audio setting, detecting an audio input, the audio input associated with an amplifier-defined audio setting and, in response to detecting the audio input, applying the amplifier-defined audio setting to the audio input.

The audio input may include a vehicle safety chime. The audio input may be associated with a frequency range characteristic of human conversational speech.

The detecting of the audio input may include detecting data activity on the system data bus. The data activity may include an audio configuration and/or setting associated with the input.

The amplifier-defined audio setting may include an equalizer configuration. The amplifier-defined audio setting may include a gain setting of the amplifier.

Methods may include powering-on the amplifier based on the detection of data activity on the system data bus. Exemplary embodiments include a connection to the system data bus. The connection allows the amplifier to sense data activity on the bus and react accordingly.

Embodiments may detect, based on data activity on the bus that a vehicle occupant has changed an audio setting. The occupant may change the audio setting by making a selection using the OEM head unit. Methods may include generating an amplifier output based on the occupant selection and the input. Embodiments may allow a unique selection of an audio setting to be applied to each audio channel present in a vehicle. Some embodiments may include an adjustable subwoofer level control.

An audio setting controlling the output of a particular channel may be adjusted by a vehicle occupant, amplifier user or determined by firmware embedded in the amplifier.

For example, a vehicle may include six channels in a “5.1 configuration” (see FIG. 1). A gain setting of the amplifier may be configured to differ across the different audio channels.

As a further example, a vehicle may be equipped with multiple listening stations. Each listening station may allow a vehicle occupant to select an output to a specific portion of the vehicle. Listening stations may allow a driver to select a first audio output, a front passenger to select a second audio output and a rear passenger to select a third audio output. A vehicle may include any suitable number of listening stations.

Because of the connection between the amplifier and the system data bus, the selection of an audio setting by a vehicle occupant may be applied to a particular output of a specific listening station. For example, the driver may select a first equalizer setting to be applied to the first audio output. The front passenger may select a second bass setting to be applied to the second audio output. The rear passenger may select a third bass setting to be applied to the third audio output.

Some embodiments may monitor a speed of a vehicle. The gain level of the amplifier may be adjusted based on the speed of the vehicle. The speed of the vehicle may be obtained based on detecting data activity on the system data bus.

Embodiments may include a visual display. The display may be positioned in the vehicle. The display may be positioned such that the display may be viewed by an occupant of the vehicle. The display may communicate information related to the amplifier to the occupant. For example, the display may communicate a temperature of the amplifier, voltage or current drawn by the amplifier, or any suitable property of the amplifier.

Based on data activity on the system data bus, the amplifier may adjust a manner of communicating information via the display.

For example, if the amplifier detects that a vehicle setting directs vehicle instrumentation to display information in “metric” units, the display will communicate information related to the amplifier in “metric” units. The display may communicate temperature of the amplifier using the Celsius temperature scale and not the Fahrenheit temperature scale. The vehicle setting may be detected based on data activity on the system data bus.

As a further example, the amplifier may adjust a brightness of the display based on data activity on the system data bus. Data activity may indicate that the vehicle's headlights are illuminated. Embodiments may be configured to dim the display when the vehicle's headlights are illuminated or to brighten the display when the headlights are off.

The amplifier related information communicated by the display may be continuously updated. The display may communicate information based on a current state of a property of the amplifier. For example, the display may communicate “real-time” temperature and voltage of the amplifier.

Embodiments may include a programmable interface. The interface may allow a user to customize a configuration of the amplifier. The configuration may include selecting an audio setting, a power setting or configuring any suitable property of the amplifier. For example, the interface may facilitate an updating of amplifier firmware.

The display may facilitate programming of the amplifier. The display may provide visual display of options available for selection by a user, visual feedback of user selections and/or confirmation of a user selection. The programming may be performed using a wireless device. The wireless device may provide visual feedback of user selections and confirmation of a selection. The programmable interface may include a spectrum analyzer.

Embodiments may include thermal overload protection. An excessive internal temperature of the amplifier may trigger a shut-down routine. The shut-down routine may prevent damage to components of the amplifier from the excessive temperature.

Embodiments may include voltage protection. If the amplifier detects that a voltage supply is too low or too high, the amplifier may execute the shut-down routine. The shut-down routine may prevent damage to components of the amplifier and/or audio equipment installed in the vehicle.

Execution of the shut-down routine and status of the amplifier may be communicated via the display. Upon execution of the shut-down routine, the amplifier may continue to output vehicle safety chimes, mobile device or navigation instructions.

Embodiments may include loudness control. Loudness control may allow selection of a maximum gain setting for the amplifier. The maximum gain setting may be selected by a user or determined by firmware embedded in the amplifier.

Illustrative embodiments of apparatus and methods in accordance with the principles of the invention will now be described with reference to the accompanying drawings, which form a part hereof. It is to be understood that other embodiments may be utilized and structural, functional and procedural modifications may be made without departing from the scope and spirit of the present invention.

As will be appreciated by one of skill in the art, the invention described herein may be embodied in whole or in part as a method, a data processing system, or a computer program product. Accordingly, the invention may take the form of an entirely hardware embodiment, an entirely software embodiment or an embodiment combining software, hardware and any other suitable approach or apparatus.

Furthermore, such aspects may take the form of a computer program product stored by one or more computer-readable storage media having computer-readable program code, or instructions, embodied in or on the storage media. Any suitable computer readable storage media may be utilized, including hard disks, CD-ROMs, optical storage devices, magnetic storage devices, and/or any combination thereof. In addition, various signals representing data or events as described herein may be transferred between a source and a destination in the form of electromagnetic waves traveling through signal-conducting media such as metal wires, optical fibers, and/or wireless transmission media (e.g., air and/or space).

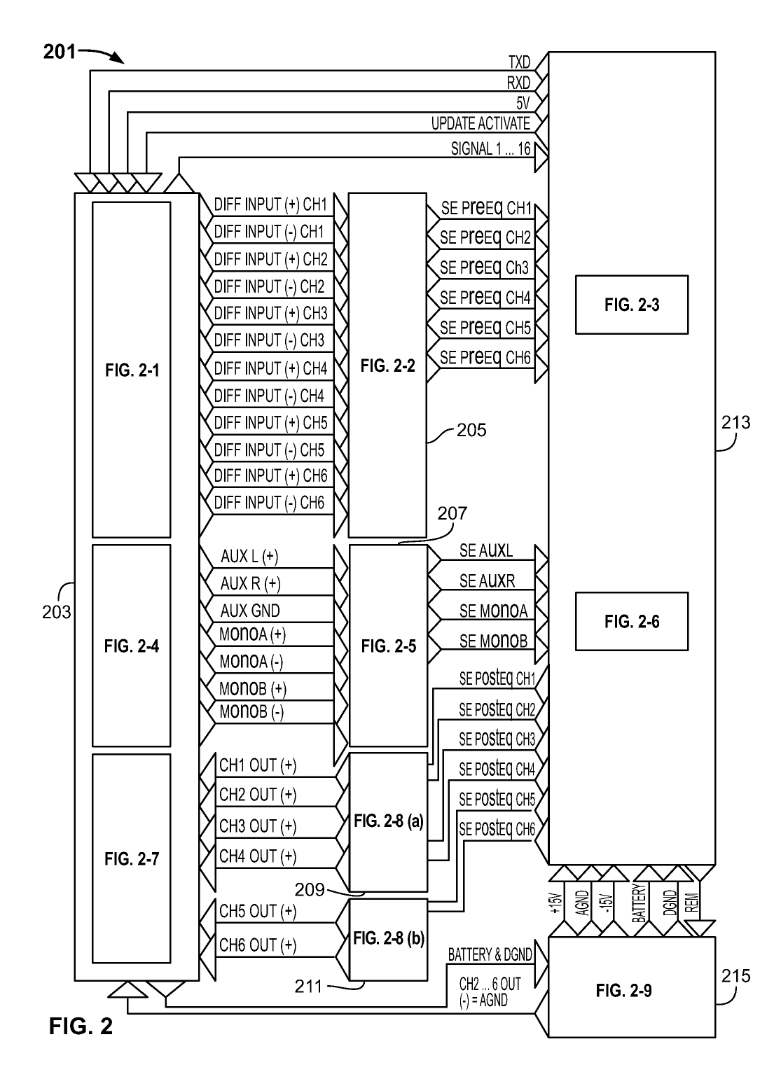

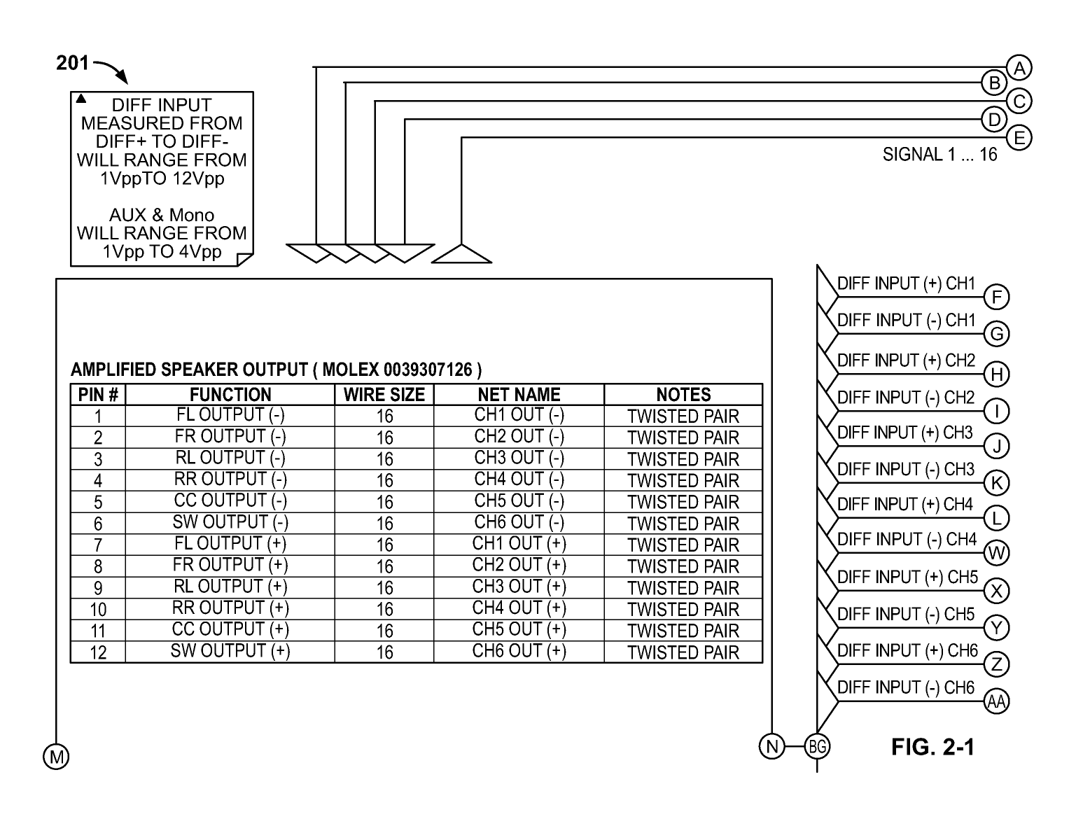

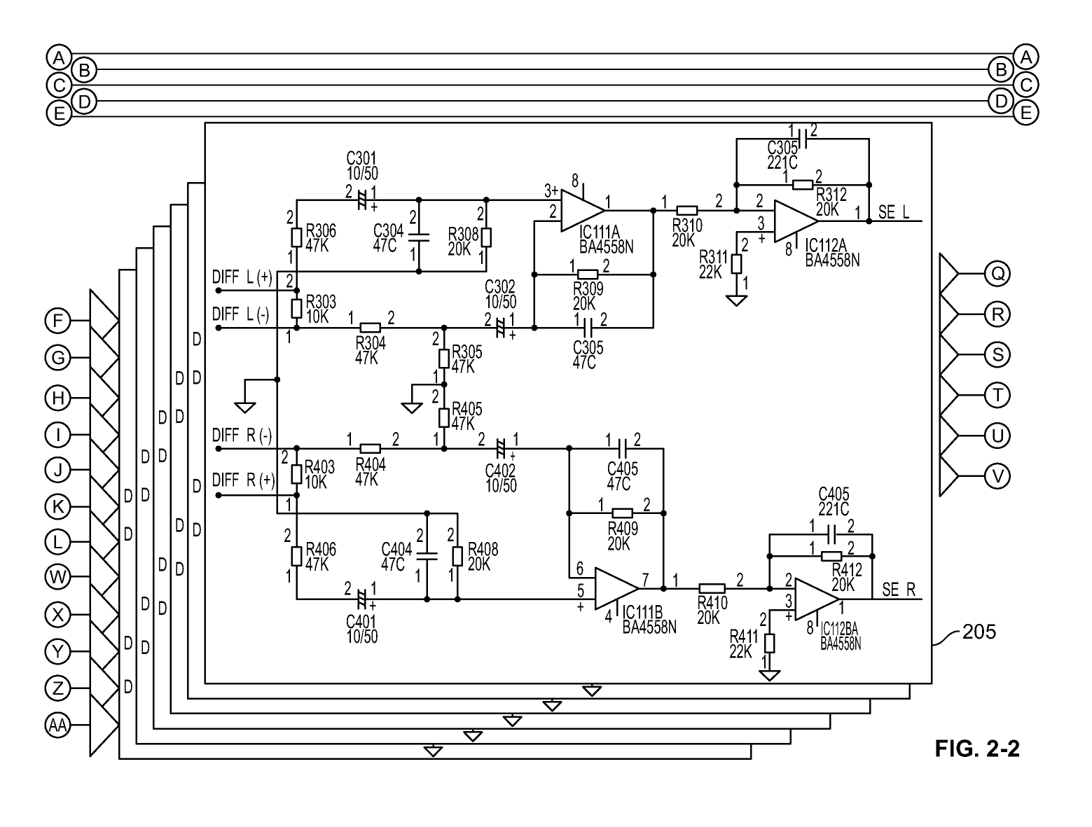

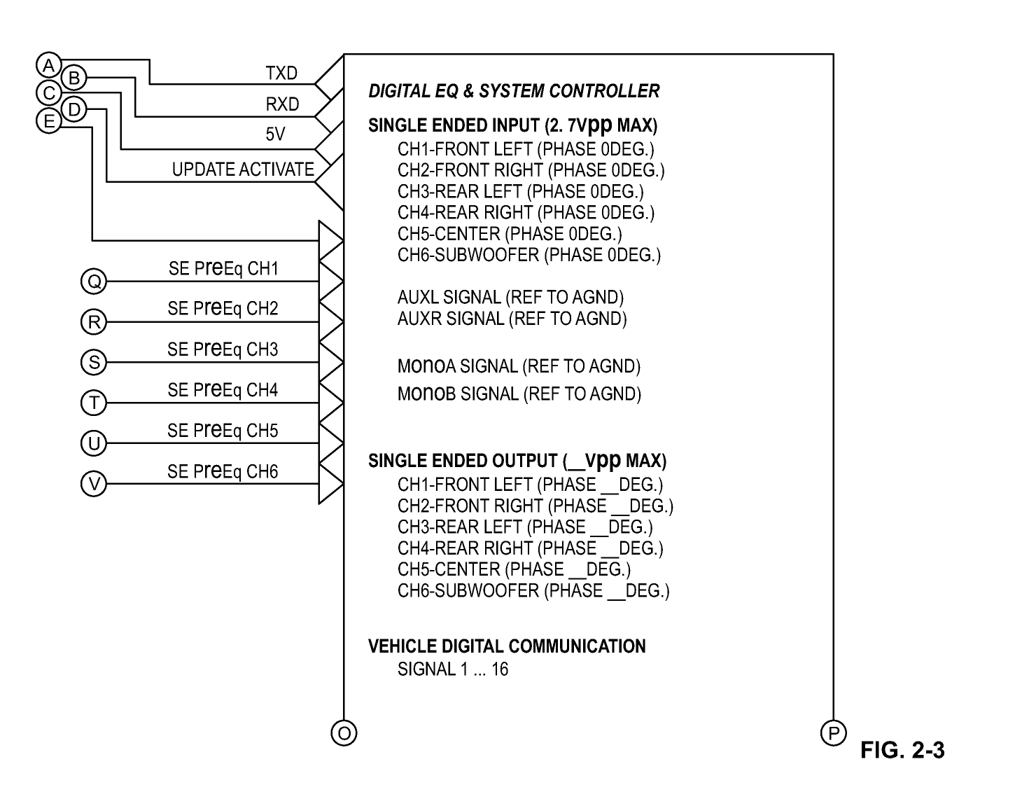

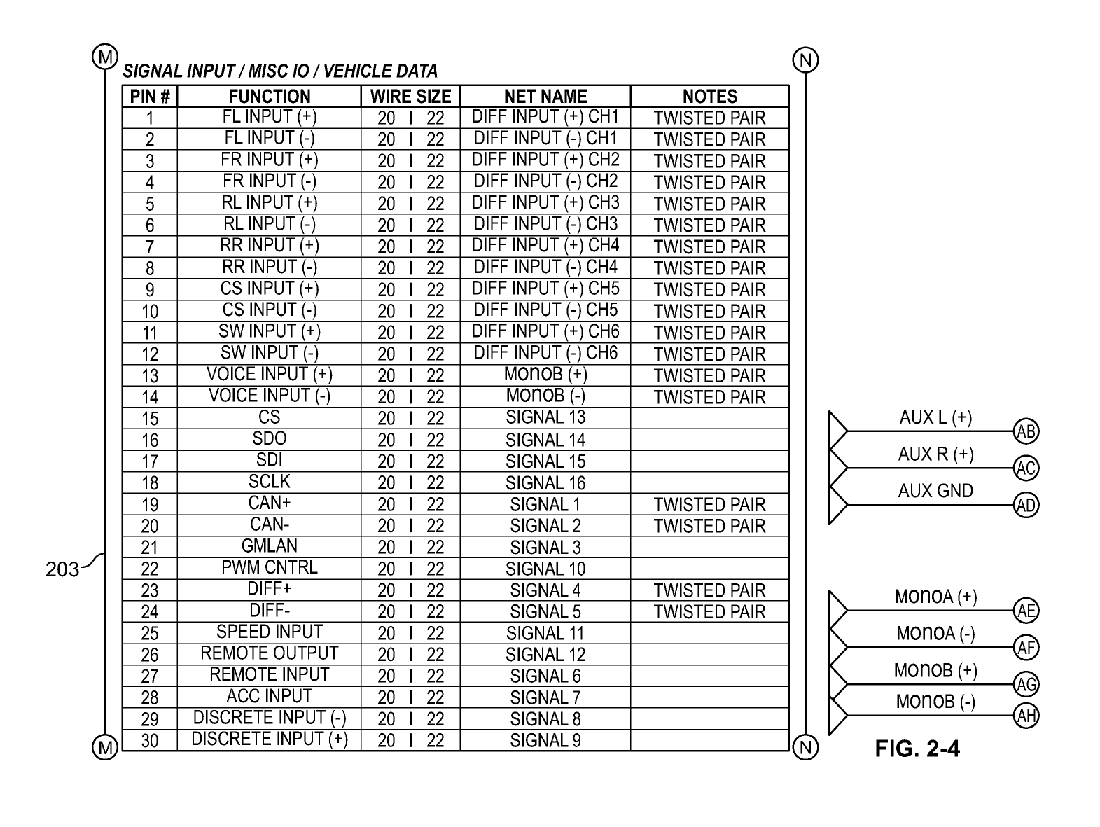

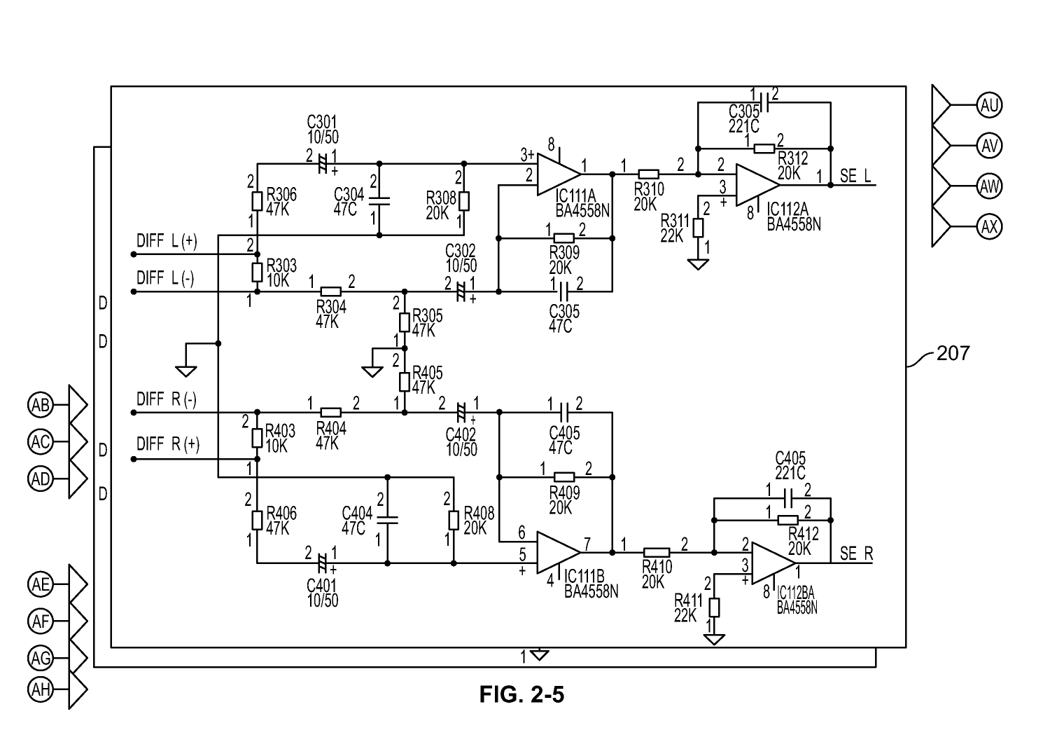

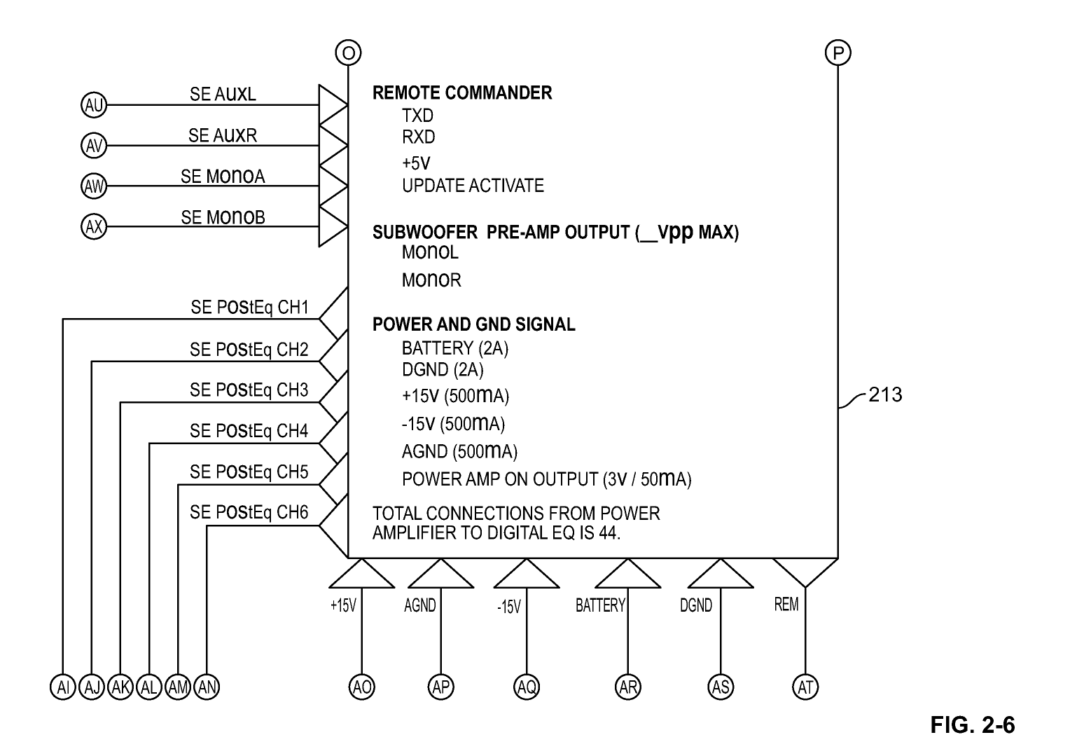

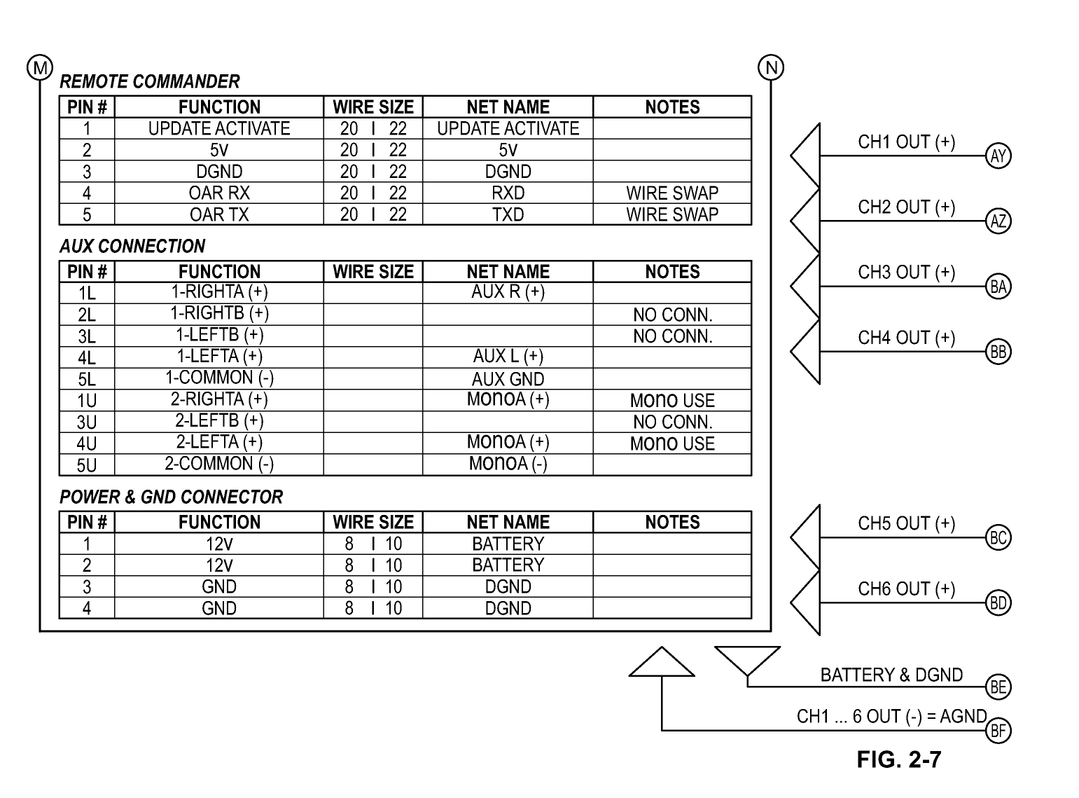

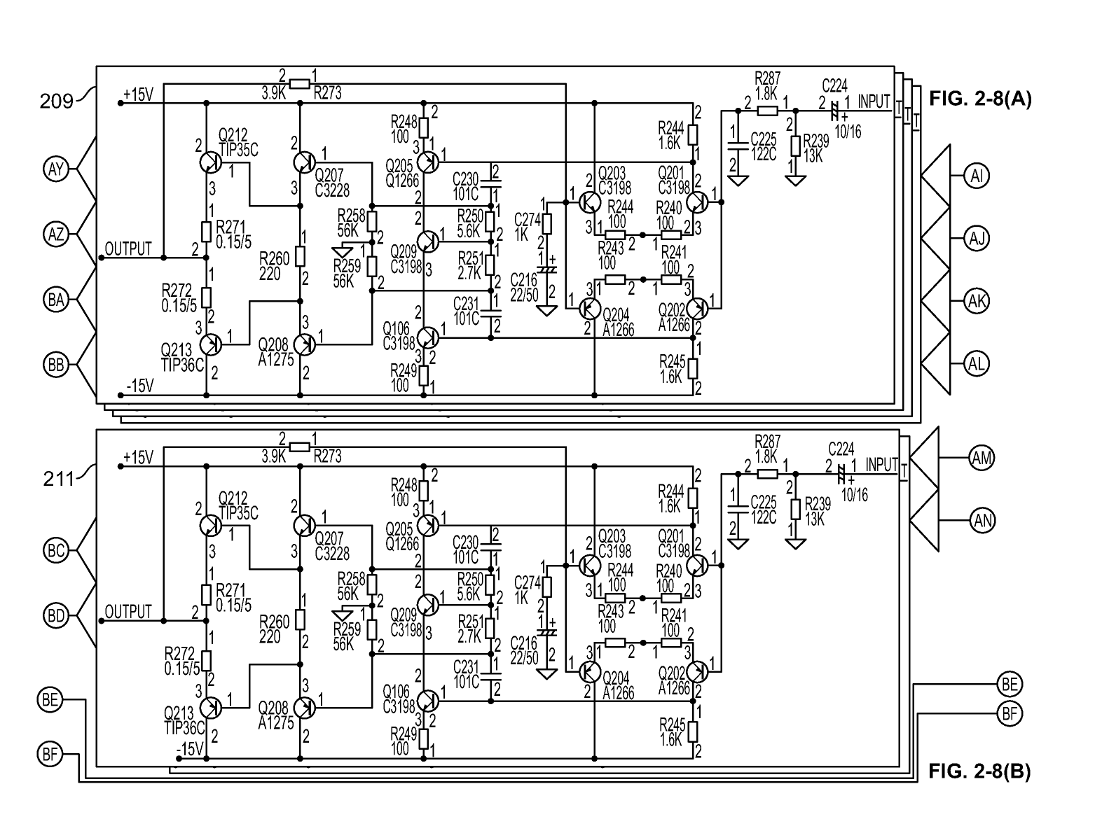

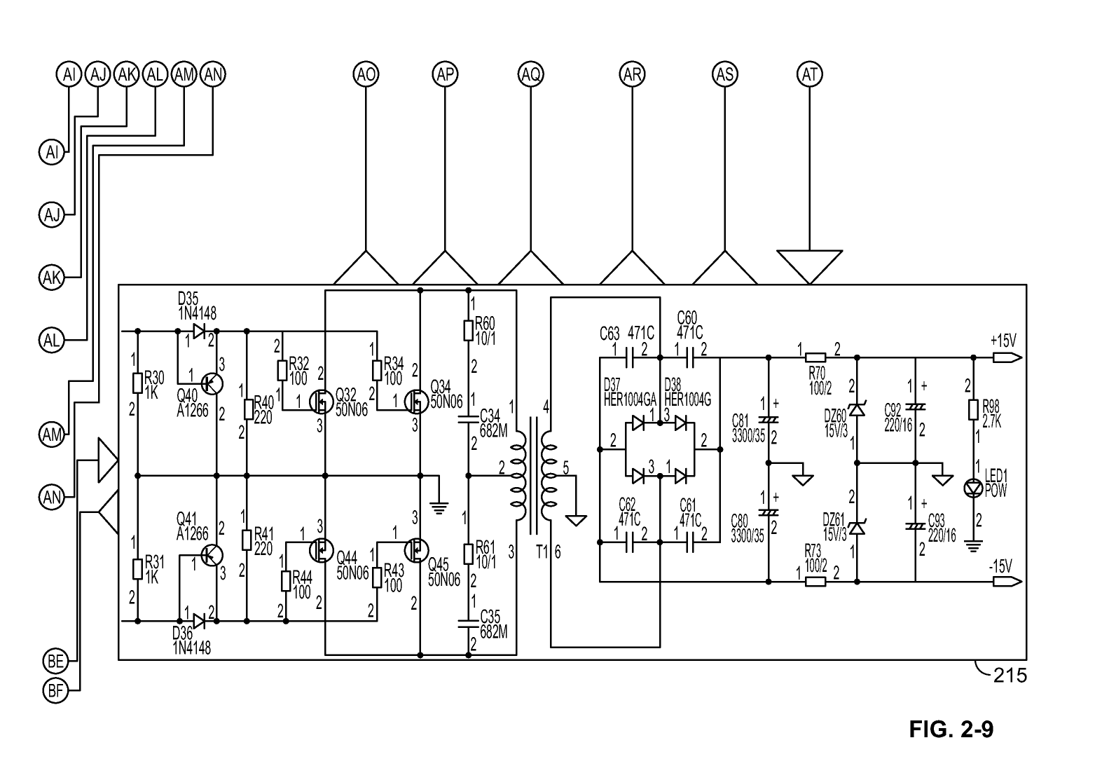

Processes in accordance with the principles of the invention may include one or more features of a “system.” The “system” may include one or more of the features of the apparatus that are shown in FIG. 2 and/or any other suitable device or approach. The “system” may be provided by an entity. The entity may be an individual, an organization or any other suitable entity.

FIG. 1 shows various system components that may interact with the OEM integration amplifier 101. A vehicle may be equipped with one of the OEM radios shown in 103a-c. The OEM radio 103a has two channels, a right and left channel. OEM radio 103b has four channels, front-left, front-right, rear-left and rear-right. OEM radio 103c has a left and right channel and/or implements a “5.1 configuration”. The OEM radio and the source audio determines the format or if 5.1 is being used. In 103c just two channels are used at a fixed level along with a variable center and sub channel. A 5.1 configuration includes three front channels (right, left and center) and two rear channels (total of five channels). There is a sixth channel (a single channel, represented by the “0.1”) that sends signals to a subwoofer. Any one of the OEM radios 103a-c may be connected to the OEM integration amplifier 101.

A digital signal processing (DSP) module 101a processes input signals from an OEM radio 103a-c. Signals from an OEM radio may be transferred by either fiber optic or coaxial cable (not shown).

Auxiliary components 105, such as a third party navigation system may be integrated into amplifier 101 and connected to DSP module 101a.

OEM integrated amplifier 101 outputs amplified and processed signals to OEM speakers 107a-e. OEM integrated amplifier 101 may also output a signal to subwoofer 107f. As shown, the five speakers correspond to five channels of output and are located in the front-left 107a, center 107b, front-right 107c, rear-right 107d and rear-left 107e positions. Subwoofer 107f corresponds to a sixth channel and may be located in any position in the vehicle.

OEM integrated amplifier 101 may also contain a RCA jack 109 to allow a connection to an additional power amplifier. RCA jack 109 contains two connections, a left pre-amplification output 109a and a right pre-amplification output 109b. RCA jack 109 may provide connectivity for an additional amplifier to be added to the vehicle.

FIG. 2 shows a circuit schematic 201 of the current invention. The invention connects to the OEM system through an interface 203. The interface 203 may also provide a connection for auxiliary inputs. Additional technical details regarding the interface 203 are shown in FIGS. 2-1, 2-4 and 2-7.

The OEM system inputs are transferred to a pre-amplification module 205. A detailed circuit schematic of pre-amplification module 205 is shown in FIG. 2-2. Auxiliary inputs are transferred to a pre-amplification module 207. A detailed circuit schematic of pre-amplification module 207 is shown in FIG. 2-5.

Pre-amplification modules 205 and 207 raise or amplify a low level analog signal to “line level.” Raising a signal to line level provides a voltage gain and facilitates further manipulation of the signal by components of the amplifier.

All inputs are then transferred from pre-amplification modules 205 and 207 to a digital signal processing module 213. The digital signal processing (DSP) module may convert signals between analog and digital forms, adjust the volume level of the signals and blend or combine the auxiliary signals with other audio signals.

The DSP module preferably converts analog input signals into digital signals for electronic processing. In some embodiments, the DSP module preferably converts the digitally manipulated signal back into analog form.

Additional technical details regarding the DSP module 213 are shown in FIGS. 2-3 and 2-6.

DSP 213 then transfers four channels of the signals to amplification modules 209 and 211. In some embodiments, the amplification module preferably performs amplification of the input signals by increasing a “gain” of the amplifier. The gain may correspond to an increase in an amplitude of the input signals.

An increase in a level of gain applied to an input signal yields a louder output signal. An occupant may select a level of gain by selecting a volume setting (not shown). The volume setting may be selected using the OEM head unit (not shown). Amplified signals are preferably directed to drive the vehicle speakers (shown in FIG. 1).

Applying the volume setting to an input may correspond to a signal manipulation of the input. The signal manipulation may be performed by DSP 213 and/or the amplification modules 209 and 211.

An output of DSP 213 may include an instruction to the amplifier modules 209 or 211 directing the modules to apply a particular level of “gain.” DSP 213 may include one or more of amplification modules 209 and 211.

A detailed circuit schematic of amplification module 209 is shown in FIG. 2-8(a). The DSP module transfers two signals corresponding to the subwoofer signal and sixth channel to amplification module 211. A detailed circuit schematic of amplification module 211 is shown in FIG. 2-8(b). In some embodiments, all six channels of signals may be passed through a single amplification module (not shown).

Upon exiting amplification module 209 or 211 the signals are transferred back to the interface 203 whereby the signals are transferred out to the vehicle's speakers (not shown). The invention also utilizes power supply 215. Power supply 215 supplies power to the amplifier and voltage sufficient to drive the vehicle speakers. A detailed circuit schematic of power supply 215 is shown in FIG. 2-9.

Note: the technical details depicted in FIGS. 2-1 to 2-9 are illustrative and do not correspond to the input and outputs associated with FIG. 2, items 203 to 215.

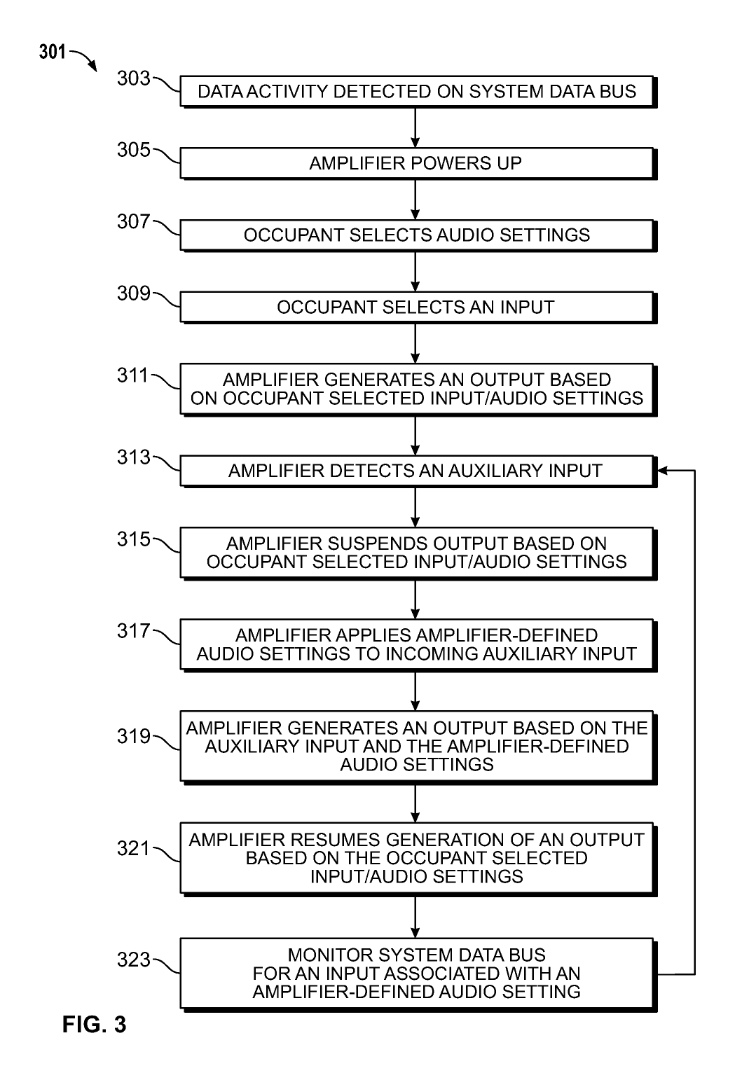

FIG. 3 shows a flow chart of an illustrative process 301 in accordance with principles of the invention.

At step 303, an aftermarket audio amplifier may detect data activity on system data bus of a vehicle. Based on the data activity, at step 305, the amplifier powers up. To initiate powering-up of the amplifier, the detected data activity may include non-audio related activity.

At step 307, a vehicle occupant selects audio settings of the amplifier. The audio setting may be selected using a programmable interface (not shown) associated with the amplifier. Exemplary audio settings (not shown) may include bass, treble, subwoofer, equalizer, fader and balance settings. The occupant may select one or more audio settings.

At step 309, the occupant selects an input. Exemplary inputs (not shown) may include music, a radio station, data stored on a portable MP3 player, an input communicated over a Bluetooth communication link, or any suitable input. At step 311, the amplifier generates an output based on the occupant selected audio setting and the occupant selected input.

At step 313, the amplifier detects an auxiliary input. Exemplary auxiliary inputs (not shown) may include a vehicle safety chime, a navigation instruction, an incoming phone call and an OnStar communication. Step 313, or other steps of process 301, may occur any anytime in process 301—e.g. prior to step 307.

At step 315, the amplifier suspends generating an output based on the occupant selected audio settings and occupant selected input. At step 317, the amplifier applies an amplifier-defined audio setting to the auxiliary input. At step 319, the amplifier generates an output based on the auxiliary input and amplifier defined audio settings.

At step 321, the amplifier resumes generating an output based on the occupant selected audio setting and the occupant selected input. At step 323, the amplifier may resume monitoring the system data bus for an input associated with an amplifier-defined audio setting.

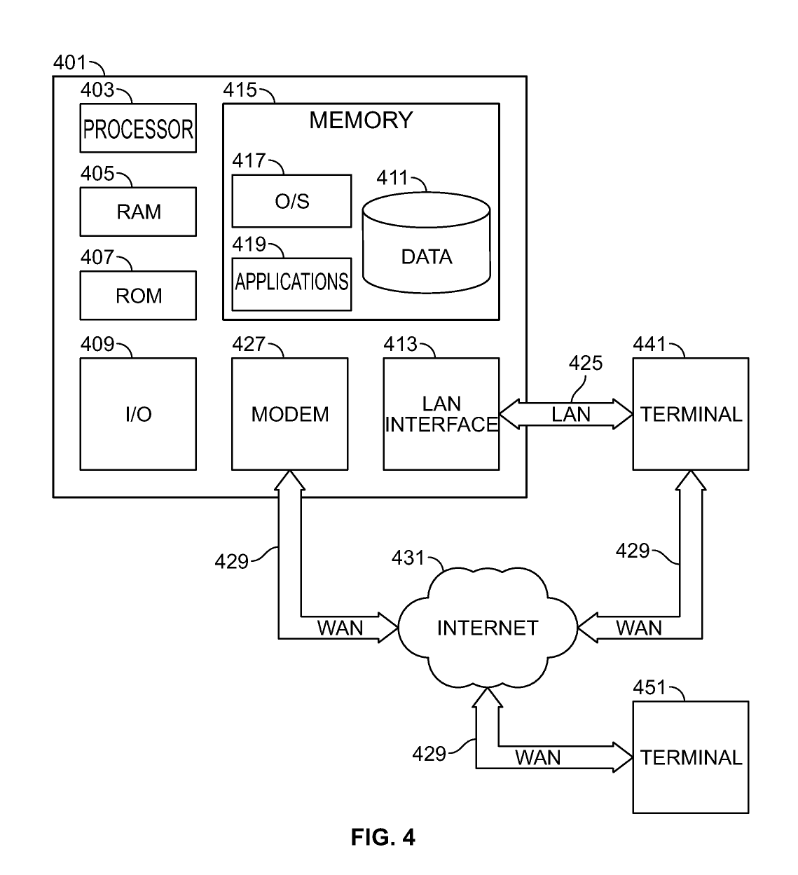

FIG. 4 is a block diagram that illustrates a generic computing device 401 (alternatively referred to herein as a “server”) that may be used in accordance with the principles of the invention. Server 401 may be included in any suitable apparatus that is shown or described herein.

Server 401 may have a processor 403 for controlling overall operation of the server and its associated components, including RAM 405, ROM 407, input/output module 409, and memory 415.

Input/output (“I/O”) module 409 may include a microphone, keypad, touch screen, and/or stylus through which a user of device 401 may provide input, and may also include one or more of a speaker for providing audio output and a video display device for providing textual, audiovisual and/or graphical output. Software may be stored within memory 415 and/or storage to provide instructions to processor 403 for enabling server 401 to perform various functions. For example, memory 415 may store software used by server 401, such as an operating system 417, application programs 419, and an associated database 411. Alternatively, some or all of server 401 computer executable instructions may be embodied in hardware or firmware (not shown). As described in detail below, database 411 may provide storage for audio settings, vehicle occupant selected settings, association between an input and an audio setting, an equalizer configuration, a gain setting, and/or any other suitable information.

Server 401 may operate in a networked environment supporting connections to one or more remote computers, such as terminals 441 and 451. Terminals 441 and 451 may be servers that include many or all of the elements described above relative to server 401. The network connections depicted in FIG. 4 include a local area network (LAN) 425 and a wide area network (WAN) 429, but may also include other networks. When used in a LAN networking environment, computer 401 is connected to LAN 425 through a network interface or adapter 413. When used in a WAN networking environment, server 401 may include a modem 427 or other means for establishing communications over WAN 429, such as Internet 431. It will be appreciated that the network connections shown are illustrative and other means of establishing a communications link between the computers may be used. The existence of any of various well-known protocols such as TCP/IP, Ethernet, FTP, HTTP and the like is presumed, and the system can be operated in a client-server configuration to permit a user to retrieve web pages from a web-based server. Any of various conventional web browsers can be used to display and manipulate data on web pages.

Additionally, application program 419, which may be used by server 401, may include computer executable instructions for invoking user functionality related to communication, such as email, short message service (SMS), and voice input and speech recognition applications.

Computing device 401 and/or terminals 441 or 451 may also be mobile terminals including various other components, such as a battery, speaker, and antennas (not shown).

Terminal 451 and/or terminal 441 may be portable devices such as a laptop, cell phone, blackberry, or any other suitable device for storing, transmitting and/or transporting relevant information.

Any information described above in connection with database 411, and any other suitable information, may be stored in memory 415.

One or more of applications 419 may include one or more algorithms that may be used to perform one or more of the following: detecting data activity on the system data bus, identifying the data activity, programming an aftermarket amplifier, and/or control operation of an aftermarket amplifier in accordance with embodiments and methods of the invention.

The invention may be operational with numerous other general purpose or special purpose computing system environments or configurations. Examples of well known computing systems, environments, and/or configurations that may be suitable for use with the invention include, but are not limited to, personal computers, server computers, hand-held or laptop devices, mobile phones and/or other personal digital assistants (“PDAs”), multiprocessor systems, microprocessor-based systems, set top boxes, programmable consumer electronics, network PCs, minicomputers, mainframe computers, distributed computing environments that include any of the above systems or devices, and the like. In a distributed computing environment, devices that perform the same or similar function may be viewed as being part of a “module” even if the devices are separate (whether local or remote) from each other.

The invention may be described in the general context of computer-executable instructions, such as program modules, being executed by a computer. Generally, program modules may include routines, programs, objects, components, data structures, etc., that perform particular tasks or store or process data structures, objects and other data types. The invention may also be practiced in distributed computing environments where tasks are performed by separate (local or remote) processing devices that are linked through a communications network. In a distributed computing environment, program modules may be located in both local and remote computer storage media including memory storage devices.

Thus, systems and methods for providing an improved aftermarket automobile audio amplifier that is easy to install and integrates and improves OEM functionality have been provided. Persons skilled in the art will appreciate that the present invention can be practiced by other than the described embodiments, which are presented for purposes of illustration rather than of limitation. The present invention is limited only by the claims that follow.

What is claimed is:

1. An aftermarket audio amplifier, the amplifier configured to:
detect a first volume setting;
detect an audio input;
adjust a gain of the amplifier to correspond to a second volume setting; and
generate an output based on the audio input and the second volume setting.

2. The amplifier of claim 1, wherein, the amplifier is further configured to re-adjust the gain of the amplifier to correspond to the first volume setting following generation of the output.

3. The amplifier of claim 1, wherein, the amplifier is configured to detect the audio input based on data activity on a system data bus, the system data bus being present in a vehicle.

4. The amplifier of claim 1 wherein the amplifier is powered-on by detection of an authorized vehicle ignition implement.

5. The amplifier of claim 1 wherein the amplifier is powered-on by detection of data activity on a system data bus, the system data bus being present in a vehicle.

6. The amplifier of claim 1 wherein the audio input comprises a vehicle safety chime.

7. The amplifier of claim 1, wherein, the first volume setting corresponds to a greater magnitude of gain of the amplifier than the second volume setting.

8. The amplifier of claim 1, wherein, the second volume setting corresponds to a greater magnitude of gain of the amplifier than the first volume setting.

9. An aftermarket audio amplifier, the amplifier configured to:
detect an input;
identify the input; and
apply an equalizer configuration associated with the input.

10. The amplifier of claim 9, wherein, the equalizer configuration is optimized for a frequency range associated with human conversational speech.

11. The amplifier of claim 9, wherein, the amplifier is further configured to apply a gain configuration associated with the input.

12. The amplifier of claim 9, wherein, the input comprises an instruction of a navigation system.

13. The amplifier of claim 9, wherein, the input comprises a portion of a conversation conducted using a mobile device.

14. The amplifier of claim 9, wherein, the input comprises a vehicle safety chime.

15. The amplifier of claim 10 wherein the equalizer configuration attenuates frequencies below 300 Hz and above 3,400 Hz.

16. The amplifier of claim 9, the amplifier further configured to identify data activity on a system data bus:
the system data bus being present in a vehicle; and
the data activity comprising the input.

17. The amplifier of claim 9, wherein, the equalizer configuration is based on data activity on a system data bus, the system data bus being present in a vehicle.

18. A method of integrating an aftermarket audio amplifier into a vehicle, the method comprising:
detecting a user-defined audio setting;
detecting an audio input, the audio input associated with an amplifier-defined audio setting; and
in response to detecting the audio input, applying the amplifier-defined audio setting to the audio input.

19. The method of claim 18, wherein, in the method, the detecting of the audio input comprises detecting data activity on a system data bus, the system data bus being present in a vehicle.

20. The method of claim 18, wherein, in the method, the amplifier-defined audio setting comprises an equalizer configuration.

21. The method of claim 18, wherein, in the method, the amplifier-defined audio setting comprises a gain of the amplifier.

22. The method of claim 18, wherein, in the method, the audio input comprises a vehicle safety chime.

23. The method of claim 18, wherein, in the method, the audio input is associated with a frequency range characteristic of human conversational speech.

24. The method of claim 18, the method further comprising powering-on the amplifier based on a detection of data activity on a system data bus, the system data bus being present in a vehicle.

25. The method of claim 18, the method further comprising:
detecting data activity on a system data bus, the data activity including an audio configuration associated with the input, the system data bus being present in a vehicle; and
generating an output based on the audio configuration and the input.

26. An aftermarket audio amplifier, the amplifier configured to:
monitor a system data bus in a vehicle; and
identify data activity on the bus;
wherein, the amplifier generates an output based on the data activity.
